(19) United States
(12) Patent Application Publication
(10) Pub. No.: US 2010/0148802 A1
(43) Pub. Date: Jun. 17, 2010

(54) CAPACITANCE-TYPE ENCODER

(75) Inventors: Hiroyuki Uchida, Minamitsuru-gun (JP); Mitsuyuki Taniguchi, Minamitsuru-gun (JP); Shunichi Odaka, Minamitsuru-gun (JP); Isao Kariya, Minamitsuru-gun (JP); Hidetoshi Mitsui, Minamitsuru-gun (JP)

Correspondence Address: DRINKER BIDDLE & REATH (DC), 1500 K STREET, N.W., SUITE 1100, WASHINGTON, DC, 20005-1209, US

(73) Assignee: FANUC LTD, Minamitsuru-gun (JP)

(21) Appl. No.: 12/581,909

(22) Filed: Oct. 20, 2009

(30) Foreign Application Priority Data
Dec. 15, 2008 (JP) 2008-318968

(51) Int. Cl. G01R 27/26

(52) U.S. Cl. 324/661

(57) ABSTRACT

A capacitance-type encoder comprising a stator, a movable element, an excitation device and a signal processing device to obtain position data with low power-consumption. The stator has excitation-electrode sets electrically independent and displaced to have phase differences from each other to form a predetermined number of excitation-electrode groups. The movable element has connection electrodes having the same number as the excitation-electrode groups. The excitation device simultaneously applies a first pair of positive and negative pulse voltages respectively to two of the excitation-electrode sets having a phase difference of 180 degrees, and then simultaneously applies a second set of positive and negative pulse voltages respectively to the rest of the excitation-electrode sets. The signal processing device determines which one of four divided regions the movable element is positioned in based on a combination of detection signals when the first and second pairs of pulse voltages are applied respectively.

### BACKGROUND OF THE INVENTION

1. Field of the Invention

The present invention relates to an encoder for detecting a relative position of a movable element such as a rotor with respect to a stator fixedly provided, and in particular to a capacitance-type encoder capable of acquiring position information with low power-consumption utilizing capacitive coupling.

2. Description of Related Art

There is known a capacitance-type encoder as a sensor for acquiring rotational information about a body of rotation. The capacitance-type encoder is capable of acquiring rotational information of the body of rotation with high sensitivity using high frequency signals and also with a thin structure utilizing a principle of capacitive coupling so that the encoder can be made small.

A capacitance-type encoder as disclosed in JP61-105421A comprises a rotary plate 10 mounted on a rotary shaft to be rotatable with respect to a body and a stationary plate 12 mounded on the body to confront the rotary plate 10 so as to detect a rotational displacement of the rotary plate with respect to the stationary plate.

A plurality of sending electrodes are arranged at regular intervals in a circumferential direction on a surface of the stationary plate. A voltage application circuit applies sinusoidal waves or rectangular waves with their phases successively displaced by a predetermined degree to the sending electrodes so that a plurality of electrode groups are formed with eight phase electrodes as a unit. For applying sinusoidal waves, it is necessary to provide a complicated analog amplifier capable of generating intermediate voltages, to increase power consumption.

Receiving electrodes having the same number as the electrode groups are arranged on a surface of the rotary plate such that each receiving electrode confronts successive sending electrodes in each electrode group on the stationary plate.

As described, in the capacitance-type encoder, there has been adopted a configuration where a plurality of sending electrodes are arranged at regular intervals and alternating voltages with predetermined displaced phases are applied to respective excitation electrodes, and receiving electrodes are arranged to confront the excitation electrodes to acquire a relative motion amount between the sending electrodes and the receiving electrodes by analyzing phase differences of capacitive signals detected by the receiving electrodes and the applied alternating voltages. It has been required to perform a position detection of a movable element such as a body of rotation with high accuracy using the capacitance-type encoder which has a small size and a light weight and also low power consumption, in view of backup of a power source of the capacitance-type encoder by a battery to maintain a function of the encoder when the power source is shut down.

### SUMMARY OF THE INVENTION

The present invention provides a capacitance-type encoder capable of obtaining position data based on signals from a movable element with low power-consumption.

A capacitance-type encoder of the present invention comprises: a stator having a plurality of excitation-electrode sets electrically independent from each other and arranged to be displaced to have phase differences from each other, each set being constituted of excitation electrodes arranged cyclically and electrically connected with each other so that a predetermined number of excitation-electrode groups are formed, and having a receiving electrode electrically independent from the excitation electrodes; a movable element provided movably relative to the stator and having connection electrodes arranged to confront the excitation electrodes of the stator cyclically to have the same number as the excitation-electrode groups, and a sending electrode electrically connected with the connecting electrodes and arranged to confront the receiving electrode of the stator; excitation means for exciting the excitation electrodes of the stator; and signal processing means for processing detection signals generated in the connection electrodes of the movable element and received by the receiving electrode through the sending electrode.

According to an aspect of the present invention, in a state where voltages of the excitation electrodes are set to respective reference voltages, said excitation means simultaneously applies a first pulse voltage to one or more of the excitation-electrode sets and a second pulse voltage to one or more of the excitation-electrode sets that have a phase difference of 180 degrees with respect to the one or more excitation-electrode sets to which the first pulse voltage is applied, directions of changes of the first pulse voltage and the second pulse voltage being opposite to each other, and after completion of the applications of the first and second pulse voltages, said excitation means simultaneously applies a third pulse voltage to one or more of the excitation-electrode sets which are different from the excitation-electrode sets to which the first and second pulse voltages are applied and a fourth pulse voltage to one or more of the excitation-electrode sets that have a phase difference of 180 degrees with respect to the one or more of the excitation-electrode sets to which the third pulse voltage is applied, directions of changes of the third pulse voltage and the fourth pulse voltage being opposite to each other, and said signal processing means stores a first detection signal received by the receiving electrode when the first and second pulse voltages are applied, and stores a second detection signal received by the receiving electrode when the third and fourth pulse voltages are applied, to determine which one of divided regions a reference line of said connection electrodes is positioned in based on a combination of the first and second detection signals, said divided regions being predetermined by dividing one cycle of arrangement of the excitation electrodes in each excitation-electrode group by four.

The excitation means may simultaneously apply the third pulse voltage to one or more of the excitation-electrode sets which have phase differences of 90 degrees with respect to the one or more of the excitation-electrode sets to which the first or second pulse voltage is applied and the fourth pulse voltage to one or more of the excitation-electrode sets which have phase differences of 180 degrees with respect to the one or more of the excitation-electrode sets to which the third pulse voltage is applied.

The excitation means may simultaneously apply the first pulse voltage to one of the excitation-electrode sets and the second pulse voltage to one of the excitation-electrode sets which have a phase difference of 180 degrees with respect to the excitation-electrode set to which the first pulse voltage is applied, and simultaneously apply the third pulse voltage to one of the excitation-electrode sets which has a phase difference of 90 degrees with respect to the excitation-electrode set to which the first or second pulse voltage is applied and the fourth pulse voltage to the excitation-electrode set which has a phase difference of 180 degrees with respect to the excitation-electrode set to which the third pulse voltage is applied.

According to another aspect of the present invention, in a state where voltages of the excitation electrodes are set to respective reference voltages, said excitation means simultaneously applies a first pulse voltage to one or more of the excitation-electrode sets and a second pulse voltage to one or more of the excitation-electrode sets that are arranged to be equivalent to an arrangement to have a phase difference of 180 degrees with respect to the one or more excitation-electrode sets to which the first pulse voltage is applied, directions of changes of the first pulse voltage and the second pulse voltage being opposite to each other, and after completion of the applications of the first and second pulse voltages, said excitation means simultaneously applies a third pulse voltage to one or more of the excitation-electrode sets which are different from the excitation-electrode sets to which the first and second pulse voltages are applied and a fourth pulse voltage to one or more of the excitation-electrode sets that are arranged to be equivalent to an arrangement to have phase differences of 180 degrees with respect to the one or more of the excitation-electrode sets to which the third pulse voltage is applied, directions of changes of the third pulse voltage and the fourth pulse voltage being opposite to each other, and said signal processing means stores a first detection signal received by the receiving electrode when the first and second pulse voltages are applied, and stores a second detection signal received by the receiving electrode when the third and fourth pulse voltages are applied, to determine which one of divided regions a reference line of said connection electrodes is positioned in based on a combination of the first and second detection signals, said divided regions being predetermined by dividing one cycle of arrangement of the excitation electrodes in each excitation-electrode group by four.

According to still another aspect of the present invention, in a state where voltages of the excitation-electrode sets are set to respective reference voltages, said excitation means simultaneously starts applications of a first voltage to one or more of the excitation-electrode sets and a second voltage to one or more of the excitation-electrode sets that have phase differences of 180 degrees with respect to the one or more of the excitation-electrode sets to which the first voltage is applied, a direction of change to the first pulse voltage from a reference voltage thereof and a direction of change to the second pulse voltage from a reference voltage thereof being opposite to each other, and stops the application of the first and second voltages after a first predetermined time period, after starting the applications of the first and second pulse voltages, said excitation means simultaneously starts applications of a third voltage to one or more of the excitation-electrode sets that are different from the excitation-electrode sets to which the first and second pulse voltages are applied, and a fourth pulse voltage to one or more of the excitation-electrode sets that have phase differences of 180 degrees with respect to the one or more of the excitation-electrode sets to which the third pulse voltage is applied, a direction of change from a reference voltage to the third pulse voltage and a direction of change from a reference voltage to the fourth pulse voltage being opposite to each other, and stops the application of the third and fourth voltages after a second predetermined time period; and said signal processing means stores a first detection signal received by the receiving electrode when the applications of the first and second excitation signals are started, and stores a second detection signal when the application of the third and fourth excitation signals are started, to determine which one of divided regions said movable element is positioned in based on a combination of the first and second detection signals, said divided regions being predetermined by dividing one cycle of arrangement of excitation electrodes in each excitation-electrode group by four, and further said signal processing means stores a third detection signal when the applications of the first and second excitation signals are stopped, and stores a fourth detection signal when the applications of the third and fourth excitation signals are stopped, to determine which one of the four divided regions said movable element is positioned in based on a combination of the third and fourth detection signals.

The excitation means may simultaneously start applications of the third voltage to one or more of the excitation-electrode sets which have phase differences of 90 degrees with respect to the one or more of the excitation-electrode sets to which the first or second voltage is applied and the fourth voltage to one or more of the excitation-electrode sets which have phase differences of 180 degrees with respect to the one or more of the excitation-electrode sets to which the third pulse voltage is applied.

The excitation means may simultaneously start applications of the first voltage to one of the excitation-electrode sets and the second voltage to one of the excitation-electrode sets which has a phase difference of 180 degrees with respect to the excitation-electrode set to which the first voltage is applied, and simultaneously apply the third voltage to one of the excitation-electrode sets which has a phase difference of 90 degrees with respect to the excitation-electrode set to which the first voltage or the second voltage is applied and the fourth voltage to the excitation-electrode set which has a phase difference of 180 degrees with respect to the excitation-electrode set to which the third voltage is applied.

The movable element may be a rotor to perform a rotary motion or a linear motion element to perform a linear motion with respect to, the stator.

In contrast to the prior art capacitance-type encoder in which high frequency alternating-current signals are continuously applied to the sending electrodes, according to the capacitance-type encoder of the present invention position data of a movable element are obtained with low power-consumption based on the signals from the movable element by applying single voltages to the excitation electrodes at appropriate frequency.

### BRIEF DESCRIPTION OF THE DRAWINGS

FIG. 1 is a front view of a stator of a capacitance-type encoder according to the present invention;

FIG. 2 is a front view of a movable element of the capacitance-type encoder;

FIG. 3 is a schematic diagram of the capacitance-type encoder;

FIG. 4 is a diagram showing positions of a connection electrode on the movable element with respect to excitation electrodes on the stator, waveforms of excitation signals applied to the excitation electrodes and detection signals according to a first embodiment of the present invention;

FIG. 5a is a table showing relation between combinations of detection signals and divided regions in which the connection electrode is positioned, and FIG. 5b is a diagram showing the divided regions of one cycle of arrangement of the excitation electrodes in the first embodiment;

FIG. 6 is a diagram showing a second embodiment of the present invention in which three excitation-electrode sets are provided;

FIG. 7a is a table showing relation between combinations of detection signals and divided regions in which the connection electrode is positioned, FIG. 7b is a diagram showing the divided regions of one cycle of arrangement of the excitation electrodes in the second embodiment, FIG. 7c is a circular representation of one cycle of the arrangement of the excitation electrodes and the connection electrode, FIGS. 7d and 7e are circular representations of one cycle of the arrangement of the excitation electrodes in a first excitation and a second excitation, respectively, FIGS. 7f and 7g are circular representations of divided regions of one cycle of the arrangement of the excitation electrodes in the first excitation and the second excitation, respectively, and FIGS. 7h-7s show relative positions of the excitation electrodes and the connection electrode when the connection electrode rotates by 30 degrees;

FIG. 8 is a block diagram showing an arrangement of a signal processing section;

FIG. 9 is a flowchart showing an algorism of processing to be performed by the signal processing section;

FIG. 10 is a diagram showing a third embodiment of the present invention in which λ number is counted;

FIG. 11 is a flowchart showing an algorism of processing in the third embodiment;

FIG. 12 a diagram showing arrangement of divided regions in the third embodiment;

FIG. 13 is a diagram showing a fourth embodiment of the present invention in which excitation signals having waveforms different from those in FIG. 4 are applied to the excitation-electrode sets;

FIGS. 14a-14c are diagrams showing time of acquisition of detection signals; and

FIG. 15 is a flowchart showing an algorism of processing to be performed in the third embodiment shown in FIG. 13.

### DETAILED DESCRIPTION

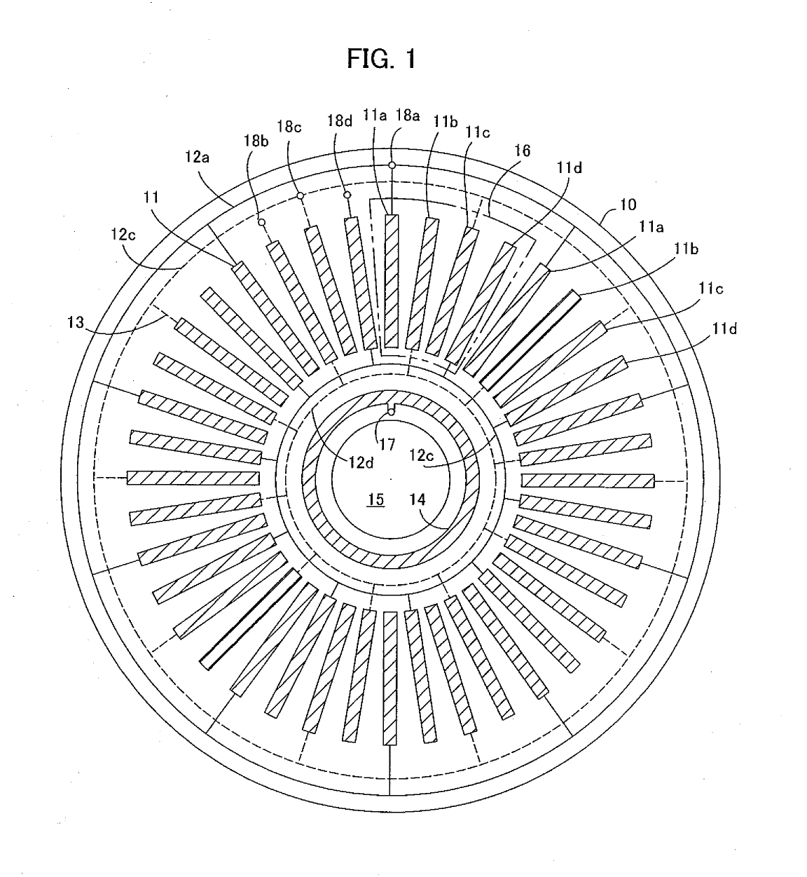

FIG. 1 shows a stator for use in a capacitance-type encoder according to the present invention. A stator 10 is a stationary disk-like plate having a through hole 15 at a center thereof and a plurality of excitation electrodes 11 arranged to extend in radial directions at constant intervals on one surface of the stator 10. The excitation electrodes 11 are arranged to form a plurality of excitation-electrode sets that are electrically independent from each other and each of the excitation-electrode sets consists of excitation electrodes arranged cyclically and electrically connected with each other, as described later.

The stator 10 is made of board material having an insulation surface and appropriate rigidity, such as glass-epoxy material, paper-Bakelite (trademark) laminated material, material obtained by applying molten ceramic to glass, ceramics such as alumina, metals such as iron and aluminum or semiconductor such as silicone, or by coating such material with isolation resin, or by isolating such material by air layer formed by isolation beads.

A conducting layer such as the excitation electrodes 11 on the stator 10 may be formed by photo-etching a conductive layer made of rolled cupper foil, evaporated chrome, etc. or by forming a conductive layer of conductive ink by inkjet, silk screen or offset printing.

Four successive excitation electrodes 11a, 11b, 11c and 11d form an excitation-electrode group 16 such that ten excitation-electrode groups in total are formed in this example. The excitation electrodes 11a, 11b, 11c or 11d in the same order in the different groups 16 are electrically connected with each other by conducting lines shown by solid lines or dotted lines in FIG. 1 to form four excitation-electrode sets 11A, 11B, 11C and 11D. The conducting lines shown by solid lines are arranged on a surface where the excitation electrodes 11 are provided, and the conducting lines shown by dotted lines are arranged on a surface opposite to the surface where the excitation electrodes 11 are provided.

As shown in FIG. 1, every fourth excitation electrodes 11a, 11b, 11c or 11d form four excitation-electrode sets 11A, 11B, 11C and 11D for four phases. The excitation electrodes in each set are electrically connected with each other via ring-shaped conductors 12a, 12b, 12c or 12d and supply conductors 13. The respective phases of the excitation electrodes are electrically excited by exciting means having four phases. In order to electrically connect every fourth excitation electrodes 11a, 11b, 11c or 11d in the respective excitation-electrode groups 16 such that the four excitation electrodes in each excitation-electrode group 16 are electrically independent from each other, the excitation electrodes, the ring-shaped conductors and the supply conductors are electrically connected by means of through-hole technique. The through-hole technique is generally known as a manufacturing technique of a printed board.

A ring-shaped receiving electrode 14 is provided to be electrically dependent from the excitation electrodes 11 at an inner portion of the stator 10 on the surface on which the excitation electrodes 11 are provided. The receiving electrode 14 is provided with a detection signal output terminal 17 for outputting detection signals received by the receiving electrode 14.

In FIG. 1, the receiving electrode 14 is arranged on the surface on which the excitation electrodes 11 are formed and at the portion inner than the excitation electrodes 11. However, the receiving electrode 14 may be provided on a surface opposite to the surface on which the excitation electrodes 11 are formed as long as the receiving electrode 14 receives detection signals by electrostatic induction with the sending electrode 22 on the movable element 20. In FIG. 1, the receiving electrode 14 is provided at the inner portion of the stator 10 so as to confront the sending electrode 22 of the movable element 20, however, the receiving electrode 14 may be provided at an outer portion of the stator 10 in a case where the sending electrode 22 is arranged at an outer portion of the movable element 20.

The through hole 15 formed at the center of the stator 10 is not an essential element of the capacitance-type encoder and may be omitted if it is not necessary for use.

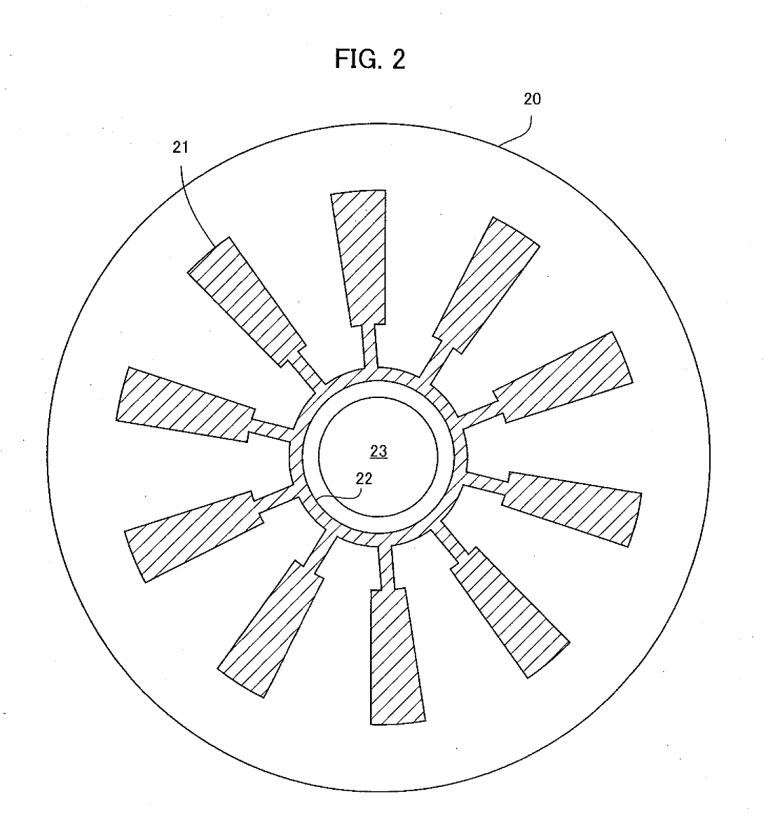

FIG. 2 shows a movable element 20 for use in the capacitance-type encoder. The movable element 20 is a disk-shaped rotor having a through hole 23. A plurality of connection electrodes 21 are formed on a surface of the movable element 20 to extend in radial directions. In the example shown in FIG. 2, ten connection electrodes 21 are provided. These connection electrodes 21 are electrically connected with a sending electrode 22 formed at a central portion of the movable element 20 so that a detection electrode of a single phase is constituted with the sending electrode 22.

The stator 10 and the movable element 20 are positioned such that the surface of the stator 10 on which the excitation electrodes 11 are formed confronts the surface of the movable element 20 on which the connection electrodes 21 are formed, so that the detection electrode constituted by the plurality of connection electrodes 21 detects excitation signals applied to the excitation electrodes 11 of the stator 10 according to the principle of electrostatic induction.

The signals generated in the detection electrode varies according to the relative position of the movable element 20 with respect to the stator 10 and the excitation signals applied to the excitation electrodes 11.

An alternating current signal of single phase detected by the detection electrode of the movable element 20 is sent to the receiving electrode 14 of the stator 10 by electrostatic induction between the sending electrode 22 on the movable element 20 and the receiving electrode 14 of the stator 10. Thus, the sending electrode 22 and the receiving electrode 14 are capable of transmitting the detection signals in a non-contact manner. A slip ring or a rotary transducer may be employed for transmitting the detection signals from the movable element 20 to the stator 10, other than the device utilizing the electrostatic induction.

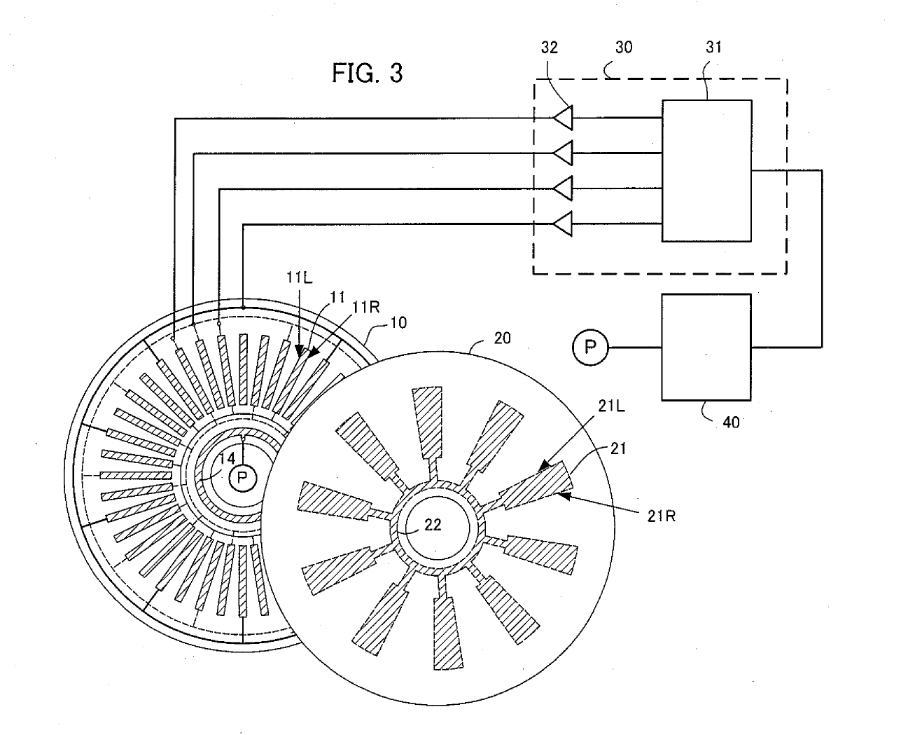

FIG. 3 schematically shows a capacitance-type encoder having the stator and the movable element according to a first embodiment of the present invention. The surface of the movable element 20 with the connection electrodes 21 provided thereon is arranged to confront the excitation electrodes 11 of the stator 10 with a predetermined gap in between and the movable element 20 is rotatably supported to be coaxial with the stator 10. The gap between the stator 10 and the movable element 20 is set generally to 150 μm to 200 μm in the case where an arranging pitch of the excitation electrodes is 200 μm, for example.

Outputs of the excitation means 30 are connected to the respective supply terminals 18a, 18b, 18c and 18d for the respective phases on the stator 10. The excitation means 30 comprises a sequencer 31 for generating signals having predetermined waveforms and a driver 32 for amplifying the signals outputted from the sequencer 31. The sequencer 31 outputs single pulse voltages at predetermined intervals. Reference voltages of the pulse voltages are not necessarily set to the same value but may be set differently for the respective excitation-electrode sets. For example, reference voltages of the excitation-electrode sets 11A and 11B are set to 0V and reference voltages of the excitation-electrode sets 11C and 11D are set to 5V. In this case, the detection signals produced by the application of the pulse voltages are clearly distinguished from a ramping change of the voltage caused when the connection electrode 21 moves from a state confronting one excitation-electrode set to another excitation-electrode set by a signal processing section 40. The detection signal output terminal 17 of the stator 10 and the signal processing section 40 are electrically connected and the detection signals SG received by the receiving electrode 14 of the stator 10 are inputted to the signal processing section 40.

A way of detecting a rotational position (angle) of the movable element by the above capacitance-type encoder will be explained below.

As described, the stator 10 is provided with four excitation-electrode sets 11A, 11B, 11C and 11D arranged to be displaced clockwise, so that the four successive excitation electrodes 11a, 11b, 11c and 11d are arranged cyclically in this order to form a plurality of excitation-electrode groups. In one cycle of arrangement of the excitation electrodes 11a, 11b, 11c and 11d, the excitation electrode 11a has arrangement phase of 0 degree, the excitation electrode 11b has an arrangement phase of 90 degrees, the excitation electrode 11c has an arrangement phase of 180 degrees and the excitation electrode 11d has an arrangement phase of 270 degrees in each excitation electrode group.

As shown in FIG. 3, a left one of two sides 21L and 21R of each connection electrode 21 extending in radial directions of the movable element 20 is set to a reference line 21L of the rotational position of the movable element 20, and a left one of two sides 11L and 11R of one excitation electrode 11 extending in radial directions is set to a reference line 11L of the position of the stator 10.

One cycle of arrangement of the excitation electrodes 11a, 11b, 11c and 11d in each excitation-electrode group 16 is divided by four, so that divided four regions, i.e. quadrants for detection of position of the connection electrodes 21 are determined using the reference line 11L of the stator 10. The capacitance-type encoder of the present embodiment determines in which divided region the reference line 21L of the connection electrode 21 is positioned with respect to the reference line 11L of the stator 10, and output the determination results.

The sequencer 31 of the excitation means 30 applies excitation signals to the excitation electrodes 11 according to the following steps. The sequencer 31 starts application of the excitation signals in a state where voltages of the excitation electrodes are equal to the respective reference voltages.

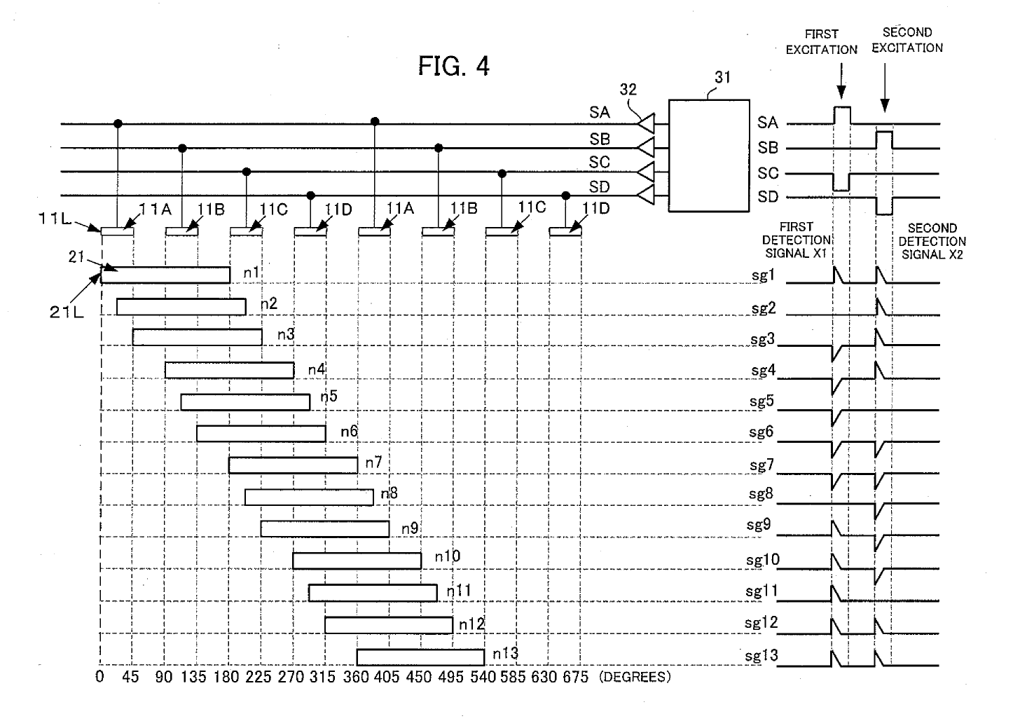

As a first step, excitation signals SA, SC having different polarities are applied to any two excitation-electrode sets (11A, 11C in the example of FIG. 4) which are different in the arrangement phase by 180 degrees in the four excitation-electrode sets (11A, 11B, 11C, 11D) to acquire a first detection signal SG. With this first step, it can be determined which one of divided regions, that are obtained by dividing one cycle of arrangement of the excitation electrodes in each excitation-electrode group by two (displaced by 180 degrees), the reference line 21L of the connection electrodes 21 is positioned in.

The detection signals SG include positive voltages and negative voltages responding to leading edges and trailing edges of the pulse voltages of the excitation signals. In this example, the signal processing section 40 operates to adopt positive voltages of the detection signals SG as effective signals and ignore the negative voltages.

As a second step, after completion of the application of the excitation signals SA, SC, excitation signals SB, SD having different polarities are applied to the rest (11B, 11D) of the excitation electrodes in the four excitation-electrode sets (11A, 11B, 11C, 11D) to acquire a second detection signal SG. Based on a combination of the detection signals acquired by the first and second applications of the excitation signals, it is determined which one of the four divided regions the reference line 21L of the connection electrodes 21 is positioned in.

After completion of the application of the excitation signals SB, SD, the reference voltage of 0V is outputted to the four excitation-electrode sets for a predetermined time period.

According to this embodiment, with the arrangement of the four sets and ten groups of excitation-electrodes 11, a rotational position of the movable element 20 can be determined with resolution of a fortieth part per one rotation of the movable element 20.

Referring to FIG. 4, how to determinate which one of the four divided regions the reference line 21L of the connection electrodes 21 is positioned in will be explained more concretely.

FIG. 4 shows various positions of the connection electrode 21 of the movable element 20 with respect to the excitation electrodes 11 on the stator 10, and also the excitation signals applied to the excitation electrodes 11 and detection signals generated at respective positions of the connection electrode 21.

As the above-mentioned first step, the sequencer 31 simultaneously outputs an excitation signal SA of a positive pulse voltage to the excitation-electrode set 11A and an excitation signal SC of a negative pulse voltage having the same amplitude as the excitation signal SA to the excitation-electrode set 11C having the phase difference of 180 degrees with respect to the excitation-electrode set 11A. Thus, a direction of change of the first pulse voltage to the excitation-electrode set 11A and a direction of change of the second pulse voltage to the excitation-electrode set 11C are opposite to each other.

Then, as the above-mentioned second step, the sequencer 31 simultaneously outputs an excitation signal SB of a positive pulse voltage to the excitation-electrode set 11B and an excitation signal SD of a negative pulse voltage having the same amplitude as the excitation signal SB to the excitation-electrode set 11D having the phase difference of 180 degrees with respect to the excitation-electrode set 11B. Thus, a direction of change of the third pulse voltage to the excitation-electrode set 11B and a direction of change of the fourth pulse voltage to the excitation-electrode set 11D are opposite to each other.

Phase angles in the arrangement of the excitation electrodes are indicated at the lower portion of FIG. 4. In the example of FIG. 4, the excitation-electrode set 11A has a phase angle of 0, 360, . . . degrees, the electrode set 11B has a phase angle of 90, 450, . . . degrees, the electrode set 11C has a phase angle of 180, 540, . . . degrees and the electrode set 11D has a phase angle of 270, 630, . . . degrees.

In FIG. 4, a left side 11L of one excitation electrode in the excitation-electrode set 11A is used as a reference line of detection of a rotational position of the connection electrode 21. The connection electrode 21 depicted at the uppermost position (n1) indicates a case where the reference line 21L is positioned at 0 degree. At this position, since the connection electrode 21 confronts the excitation-electrode set 11A and the excitation electrode-set 11B, a positive detection signal SG (a first signal in sg1) appears at the first step, and subsequently a positive detection signal SG (a second signal in sg1) appears at the second step.

Then, when the reference line 21L of the connection electrode 21 is shifted to be positioned at 22.5 degrees (n2), the connection electrode 21 confronts a part of the excitation-electrode set 11A, a part of the excitation-electrode set 11C having the same area as the part of the excitation-electrode set 11A and the whole of the excitation-electrode set 11B. Thus, no detection signal (0V) appears at the first step as a result of cancellation, and subsequently a positive detection signal SG (a second peak in sg2) appears at the second step.

Next, at the position where the reference line 21L of the connection electrode 21 is positioned at 45 degrees (n3), the connection electrode 21 confronts the excitation-electrode set 11B and the excitation-electrode set 11C. Thus, a negative detection signal (a first signal in sg3) appears at the first step, and subsequently a positive detection signal SG (a second signal in sg3) appears at the second step. This status is maintained until the reference line 21L reaches the position of 112.5 degrees.

Then, when the reference line 21L of the connection electrode 21 is shifted to be positioned at 112.5 degrees (n5), the connection electrode 21 confronts the excitation-electrode set 11B, the excitation-electrode set 11C and the excitation-electrode set 11D. Thus, a negative detection signal (a first signal in sg5) appears at the first step, and subsequently no detection signal appears at the second step since the excitation by the excitation-electrode set 11B and the excitation by the excitation-electrode set 11D are cancelled.

Subsequently, in the manner as described, in the range between 112.5 degrees to 202.5 degrees negative detection signals appear at the first and second steps, in the range between 202.5 and 292.5 a positive detection signal appears at the first step and a negative detection signal appears at the second step and in the range between 292.5 and 360 degrees positive detection signals appear in the first and second steps.

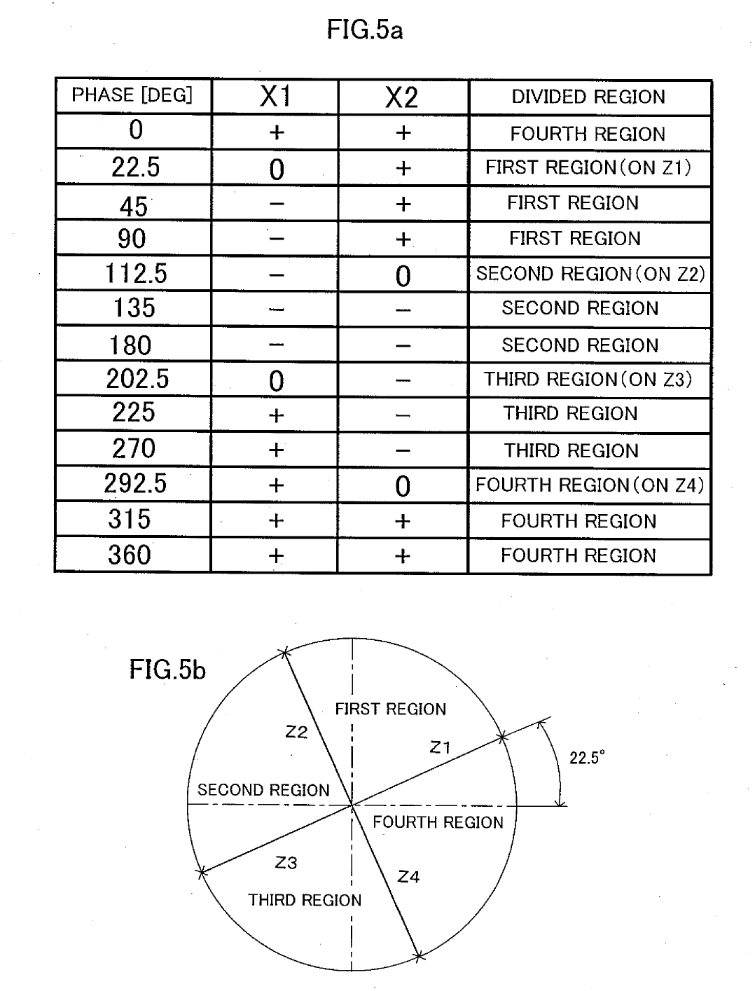

FIG. 5a shows a status data table storing relation between combinations of detection signals SG and divided regions in which the reference line of the connection electrode is positioned, as shown in FIG. 4. Referring to the status data table, it can be determined in which region the reference line 21 L of the connection electrode 21 is positioned based on the combination of the detection signals SG acquired in the first step and the second step. Lines Z1 to Z4 shown in FIG. 5b are boundaries of the divided regions and these lines are included in the first to fourth regions, respectively. In FIG. 5a, X1 and X2 respectively represent the first and second detection signals which appear in the receiving electrode 14 using a positive sign (+), 0 and a negative sign (−).

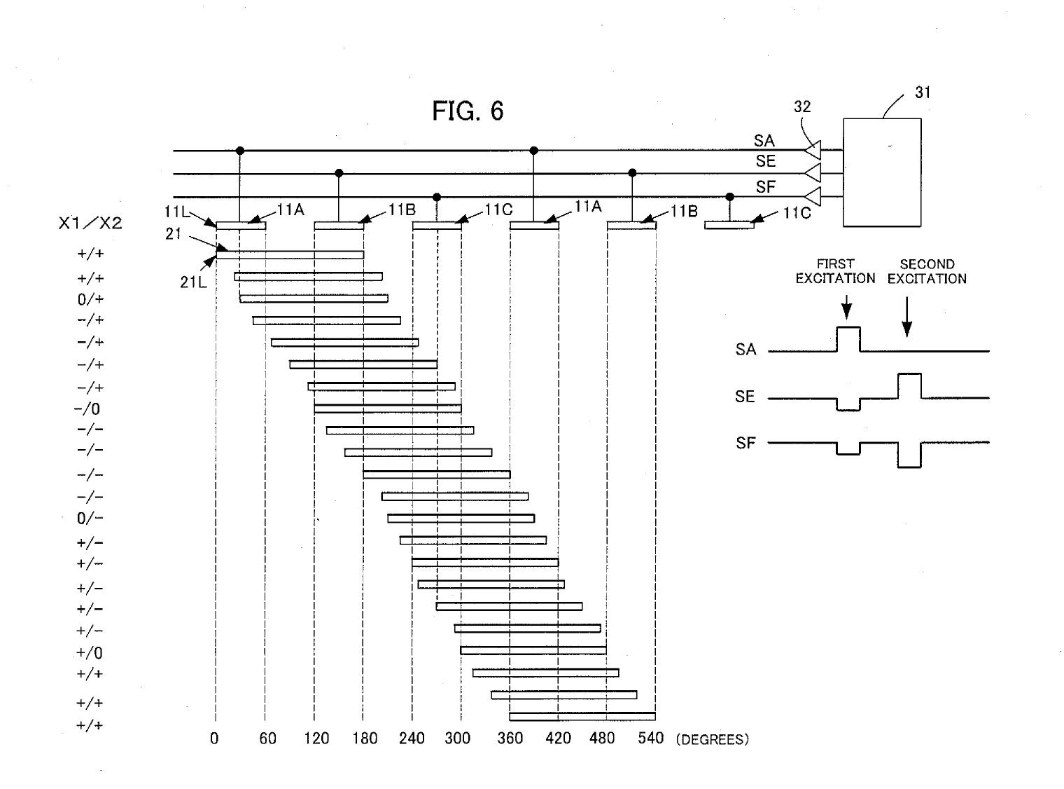

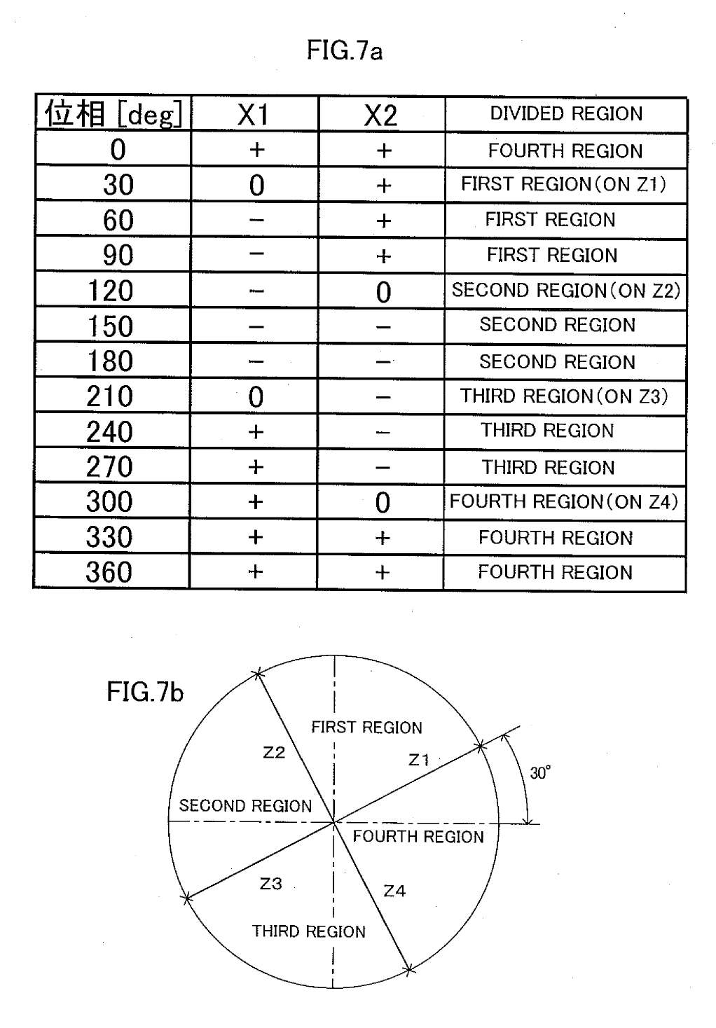

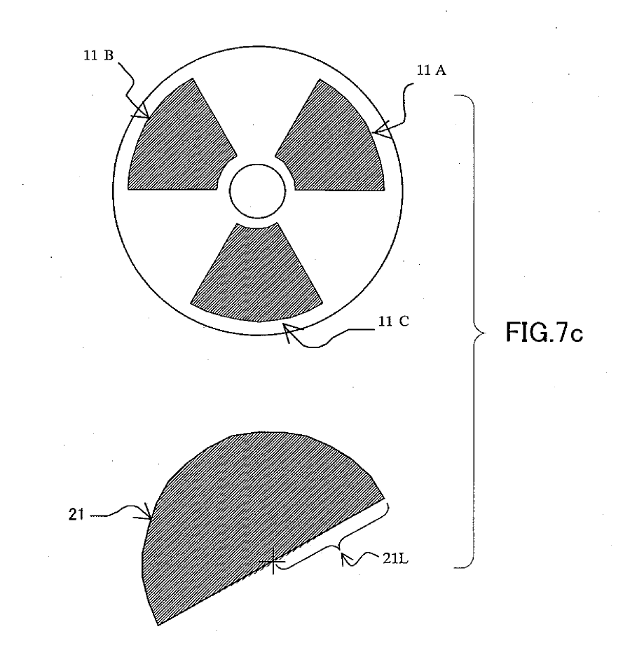

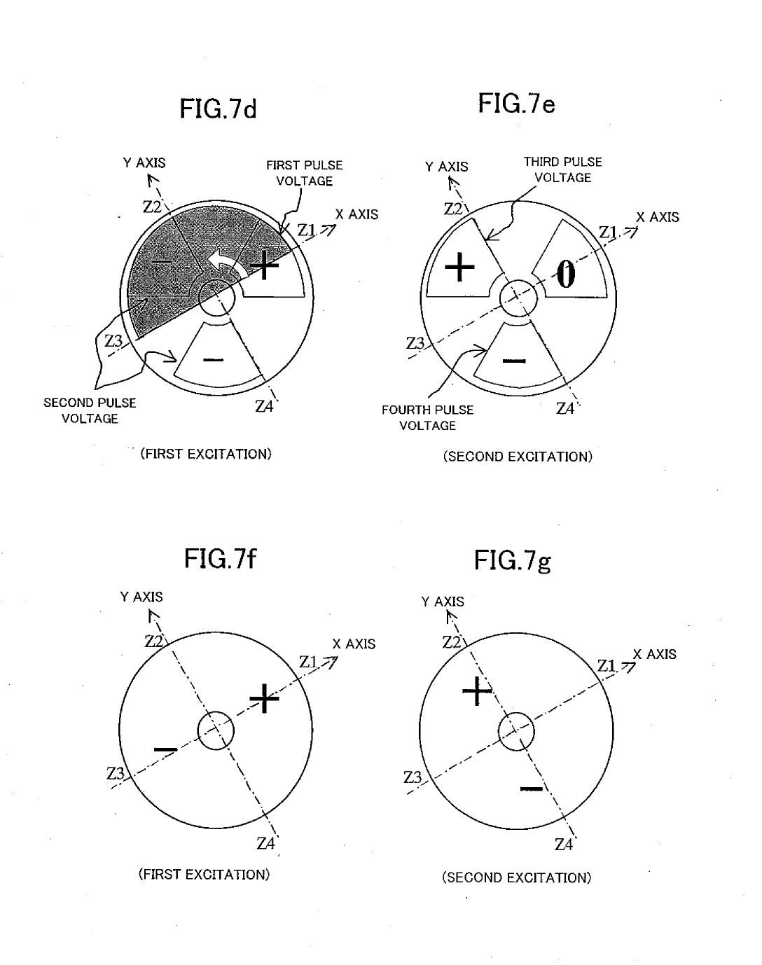

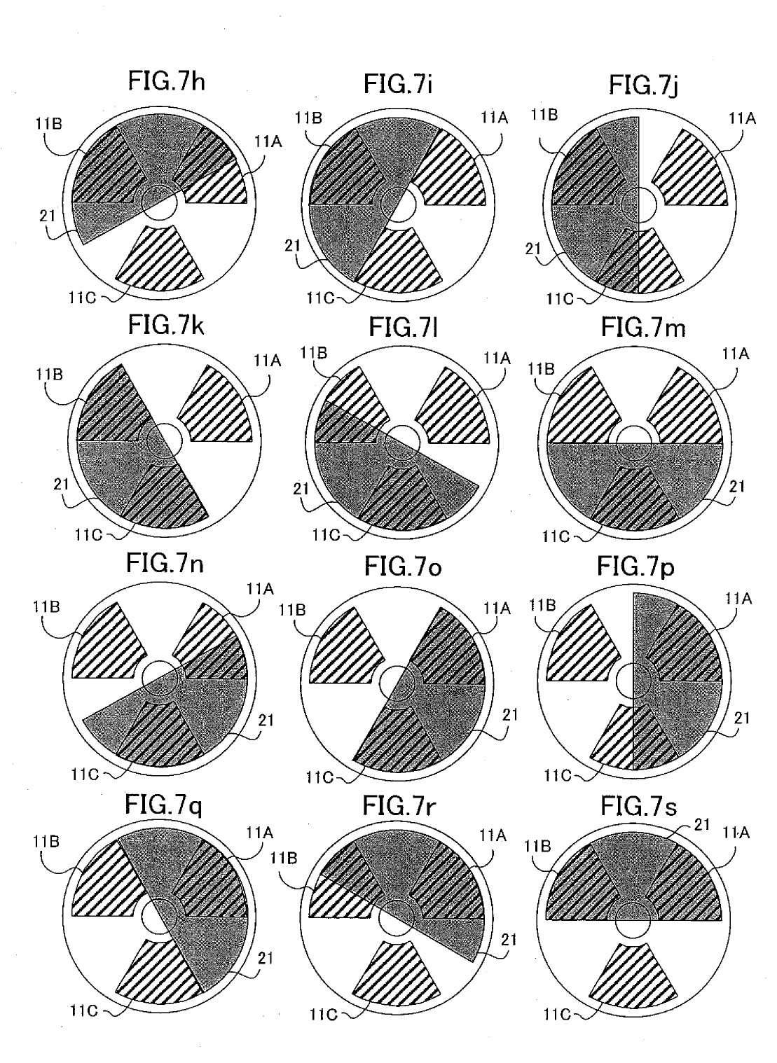

Referring to FIGS. 6 and 7a-7s, a second embodiment in which three excitation-electrode sets are provided will be explained. This embodiment is different from the first embodiment shown in FIGS. 4, 5a and 5b in combinations of excitation-electrode sets to be excited and signal levels of the excitation signals in the first step and the second step.

In this embodiment, the stator includes three excitation-electrode sets 11A, 11B and 11C arranged clockwise in this order. As the excitation-electrode sets 11A, 11B and 11C are arranged to be displaced by 120 degrees, a combination of the excitation electrodes to be excited are different from that of the first embodiment.

In this embodiment, the sequencer 31 of the excitation means 30 applies excitation signals to the excitation electrodes 11 according to the following steps.

In a first step, all of the three excitation-electrode sets are excited. The sequencer 31 simultaneously applies an excitation signal SA of a positive pulse voltage to the excitation-electrode set 11A and excitation signals SE and SF of negative voltages to the excitation-electrode set 11B and the excitation-electrode set 11C which are short-circuited. An amplitude of the negative voltages applied to the excitation-electrode sets 11B and 11C is set to half of an amplitude of the positive voltage applied to the excitation-electrode set 11A. A first detection signal is obtained in response to the simultaneous application of a first pulse voltage of the excitation signal SA and a second pulse voltage of the excitation signals SE and SF.

Then, in a second step, no pulse voltage is applied to the excitation-electrode set 11A (i.e. maintained at the reference voltage), a positive pulse voltage is applied to the excitation-electrode set 11B and simultaneously a negative pulse voltage having the same amplitude as the positive voltage is applied to the excitation-electrode set 11C. A second detection signal is obtained in response to the simultaneous application of a third pulse voltage of the excitation signal SE and a fourth pulse voltage of the excitation signal SF. With the above two steps, it is possible to determine in which one of the four divided regions the reference line 21L of the connection electrodes 21 is positioned in the same manner as the first embodiment.

It is assumed that the voltages of the respective excitation-electrode sets are represented as vectors on an X-Y coordinate system. In FIGS. 7b and 7d-7g, a line defined by the boundaries Z1 and Z3 is regarded as X axis with positive direction thereof defined as a direction from the boundary Z3 to the boundary Z1, and a line defined by the boundaries Z2 and Z4 is regarded as Y axis with positive direction thereof being defined as a direction from the boundary Z4 to the boundary Z2. When the reference line 21L of the connecting electrode 21 is positioned to align the X axis, no detection signal is present in response to the simultaneous application of the first and second pulse voltages. When the reference line 21L of the connecting electrode 21 is positioned to align the Y axis, no detection signal is present in response to the simultaneous application of the third and fourth pulse voltages. Thus, the X axis defined by the boundaries Z1 and Z3 and the Y axis defined by the boundaries Z2 and Z4 are borders of an area in which a positive detection signal is present and an area in which a negative detection signal is present. Assuming that the connecting electrode 21 rotates in one direction as indicated by an arrow in FIG. 7d, a sign of the first detection signal changes from positive to negative and negative to positive when the reference line 21L of the connecting electrode 21 transits the boundary Z1 and the boundary Z3, respectively. Likewise, a sign of the second detection signal changes from positive to negative when the reference line 21L of the connecting electrode 21 transits the boundary Z2 and the boundary Z4. Thus, the transition of the boundary Z1 and the transition of the boundary Z3 of the reference line 21L are distinguished by the first detection signal and the transition of the boundary Z2 and the transition of the boundary Z4 of the reference line 21L are distinguished by the second detection signal, so that it is determined which one of the first to fourth divided regions the reference line 21L of the connection electrode 21 is positioned in based on a combination of the first and second detection signals. Further, when the first detection signal is zero it can be distinguished which half of the one cycle the connection electrode is positioned in based on the second detection signal, and when the second detection signal is zero it can be distinguished which half of the one cycle the connection electrode is positioned in based on the first detection signal. In the first step, since the direction of change of the pulse voltage of the excitation signal SA to the excitation-electrode set 11A is opposite to the direction of changes of the pulse voltages of the excitation signals SE and SF to the excitation-electrode sets 11B and 11C, respectively, and the voltage changes of the respective excitation-electrode sets are transmitted to the connection electrode 21 through the capacitive coupling, the simultaneous application of the excitation signals SA, SE and SF is equivalent to a simultaneous application of a positive voltage and a negative voltage having the same amplitude as the positive voltage on the X axis. Thus, the first pulse voltage to the excitation-electrode set 11A and the second pulse voltage to the excitation-electrode sets 11B and 11C that are arranged to be equivalent to an arrangement to have a phase difference of 180 degrees with respect to the excitation-electrode set 11A are simultaneously applied. Similarly, in the second step, the simultaneous application of the excitation signals SE and SF is equivalent to a simultaneous application of a positive voltage and a negative voltage having the same amplitude as the positive voltage on the Y axis. Thus, the third pulse voltage to the excitation-electrode set 11B and the fourth pulse voltage to the excitation-electrode set 11C that is arranged to be equivalent to an arrangement to have a phase difference of 180 degrees with respect to the excitation-electrode set 11B are simultaneously applied.

In the first step, the simultaneous application of the excitation signals SA, SE and SF is equivalent to a simultaneous application of an excitation signal higher than the reference voltage and an excitation signal lower than the reference voltage to two regions (divided by the Y axis) corresponding to two halves of the one cycle (360° in electric degree) of the arrangement of the excitation electrodes, as shown in FIG. 7f. Since the connecting electrode 21 has a shape covering a half cycle of the arrangement of the excitation electrodes as shown in FIG. 7c, the sign of the first detection signal becomes positive, negative or zero in dependence on the rotational position of the connection electrode 21. In particular, the sign of the first detection signal changes positive, zero, negative, zero, positive, . . . cyclically with the rotation of the connection electrode 21 in one direction, as shown in FIGS. 7h-7s. Thus, the one cycle of the arrangement of the excitation electrodes is divided into two regions in which the first detection signal has a positive value and a negative value with the boundaries Z1 and Z3 where the first detection signal is zero.

In the second step, the simultaneous application of the excitation signals SE and SF is equivalent to a simultaneous application of an excitation signal higher than the reference voltage and an excitation signal lower than the reference voltage to two regions (divided by the X axis) corresponding to two halves of the one cycle (360° in electric degree) of the arrangement of the excitation electrodes, as shown in FIG. 7g. The sign of the second detection signal becomes positive, negative or zero in dependence on the rotational position of the connection electrode 21. In particular, the sign of the second detection signal changes positive, zero, negative, zero, positive, . . . cyclically with the rotation of the connection electrode 21 in one direction, as shown in FIGS. 7h-7s. Thus, the one cycle of the arrangement of the excitation electrodes is divided into two regions in which the second detection signal has a positive value and a negative value with the boundaries Z2 and Z4 where the second detection signal is zero.

In the above described manner, it is determined which one of the four divided regions the reference line 21L of the connection electrodes 21 is positioned in based on the combination of the first detection signal and the second detection signal.

In the above second embodiment, reference voltages of the excitation-electrode sets 11A, 11B and 11C are set to the same value of 0V, however, the reference voltages are not necessarily set to the same value but may be set differently for the respective excitation-electrode sets.

FIG. 7a shows a status data table storing relation between combinations of detection signals and divided regions in which the connection electrode is positioned as shown in FIG. 6. Referring to the status data table, it can be determined which one of the four divided regions as shown in FIG. 7b the reference line 21L of the connection electrodes 21 is positioned in based on the combination of the detection signals SG acquired in the first and second steps. Lines Z1 to Z4 in FIG. 7b are boundaries of the divided regions and these lines are included in the first to fourth regions, respectively. X1 and X2 respectively represent the first and second detection signals which appear in the receiving electrode 14 using a positive sign (+), 0 and a negative sign (−).

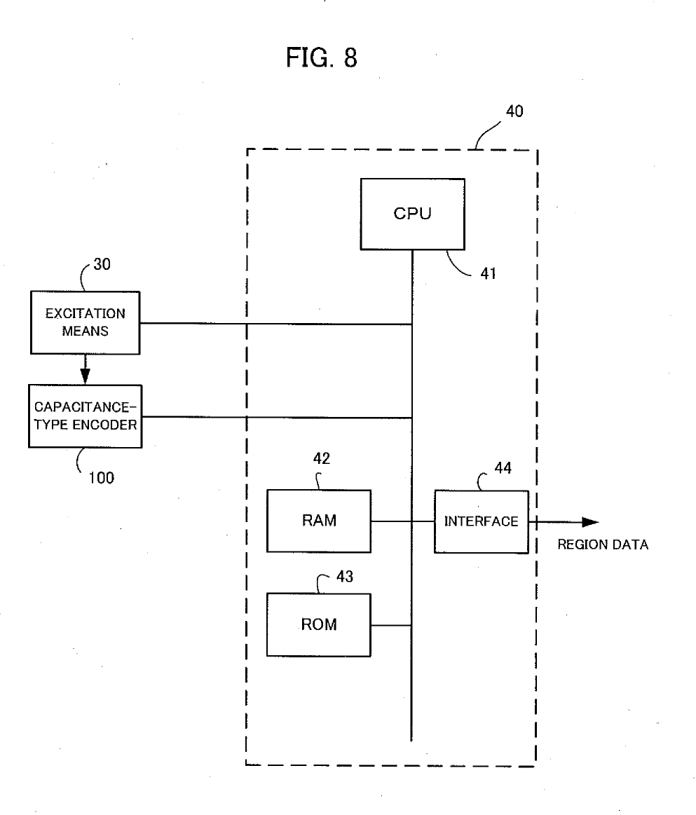

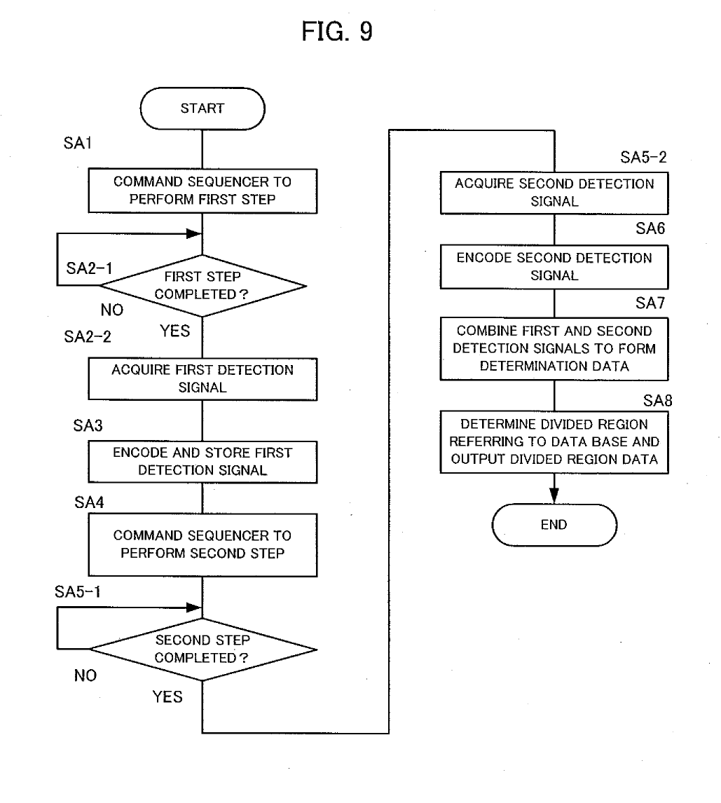

An embodiment of the signal processing section 40 will be explained referring to FIG. 8 and the processing to be performed by the signal processing section 40 will be explained referring to FIG. 9. The signal processing section 40 receives the first detection signal from the capacitance-type encoder 100 and stores the received signal in the RAM 42. Then, the acquired second detection signal is combined with the stored first detection signal and status data are read from the status data table in the ROM 43 based on the combined data. These arithmetic operations are performed by the CPU 41.

An algorithm of the processing shown in FIG. 9 will be explained.

[Step SA1]: Execution of the first step is commanded to the sequencer.

[Step SA2]: It is determined whether a signal of completion of the first step is outputted from the sequencer. If it is determined that the signal of completion is outputted a detection signal is acquired, and if not the determination is continued.

[Step SA3]: The detection signal is encoded. Each detection signal may take one of three statuses of a positive value, zero and a negative value, and thus can be represented by two-bit information. The encoded signal is stored.

[Step SA4]: Execution of the second step is commanded to the sequencer.

[Step SA5]: It is determined whether a signal of completion of the second step is outputted from the sequencer. If it is determined that the signal of completion is outputted, a detection signal from the receiving electrode is acquired, and if not, the determination is repeated.

[Step SA6]: The detection signal is encoded. Each detection signal may take one of three statuses of a positive value, zero and a negative value, and thus can be represented by two-bit information.

[Step SA7]: The detection signal acquired in Step SA3 and the detection signal acquired at Step SA6 are combined according to a predetermined rule to form determination data.

[Step SA8]: It is determined in which divided region the reference line of the connection electrodes is positioned based on the determination data referring to the status data table storing the relation between the combination of the detection signals and the corresponding divided-region, and the determined divided-region data are outputted.

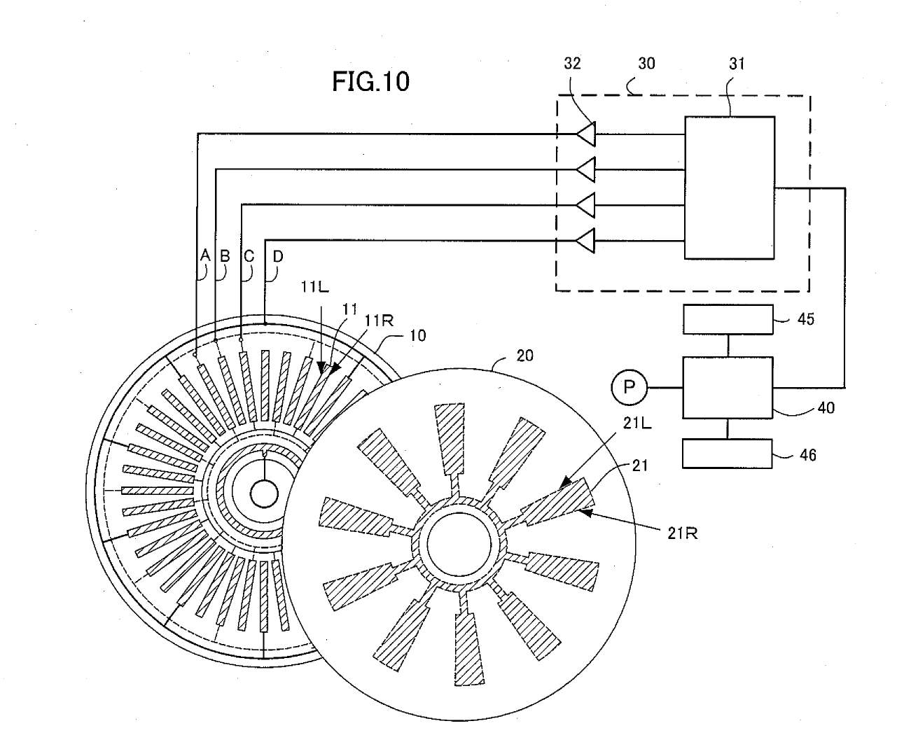

A third embodiment of the present invention will be described referring to FIGS. 10-12.

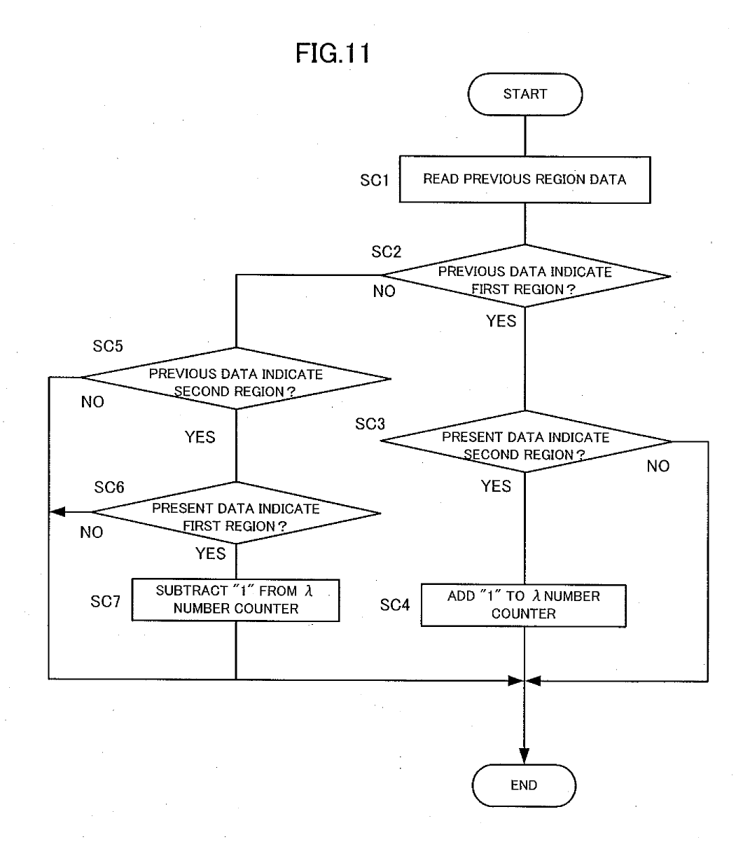

FIG. 10 shows a capacitance-type encoder having four-phase excitation electrodes 11 in which a signal processing section 40 has a region register 45 for storing the preceding divided region data, and a λ number counter 46 for storing the λ number which is updated each time when the movement of the movable element 20 exceeds one λ (one cycle of the arrangement of excitation electrodes). The way of counting the λ number using the region register and the λ number counter will be explained referring to FIG. 11.

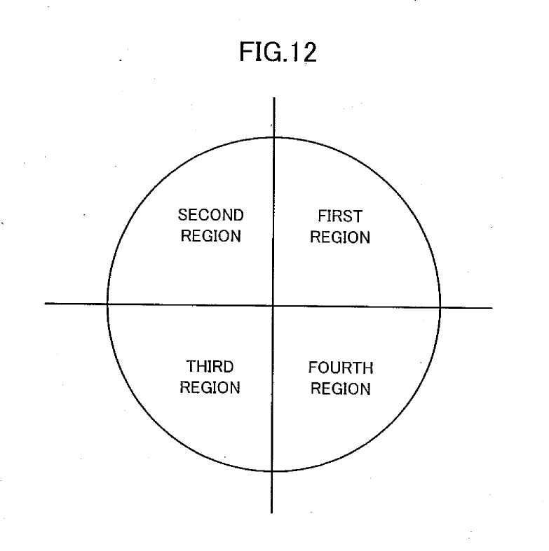

As shown in FIG. 12, a first divided region to a fourth divided region are predetermined in counterclockwise. In this example, a boundary between the first region and the second region is set to a changeover of λ number such it is determined that the movable element 20 has moved over 1λ when the reference line 21L of the connection electrode 21 enters the second region from the first region. The motion from the first region to the second region clockwise is within one λ so that the λ number counter is not updated. A first step of the determination is to determine whether the value of the region register indicates the first region or the second region. As a second step, it is determined whether the region data obtained in the present processing period indicates the first region or the second region.

Respective steps of the flowchart shown in FIG. 11 will be explained.

[Step SC1]: The previous region data are read.

[Step SC2]: It is determined whether the previous region data indicate the first region or not. If the previous region data are determined to indicate the first region the procedure proceeds Step SC3, and if not the procedure proceeds Step SC5.

[Step SC3]: It is determined whether the present region data indicate the second region. If the present region data are determined to indicate the second region the procedure proceeds Step SC4, and if not the procedure is terminated.

[Step SC4]: The λ number counter is increased by “1” and stored.

[Step SC5]: It is determined whether the previous region data indicate the second region. If the previous region data are determined to indicate the second region the procedure proceeds Step SC6, and if not the procedure is terminated.

[Step SC6]: It is determined whether the present region data indicate the first region. If the present region data are determined to indicate the first region the procedure proceeds Step SC7, and if not the procedure is terminated.

[Step SC7]: The λ number counter is decreased by “1” and stored, and the procedure is terminated.

With this embodiment, a rotational position of the movable element 20 over a plurality of cycles of the arrangement of the excitation electrodes 11 can be detected securely.

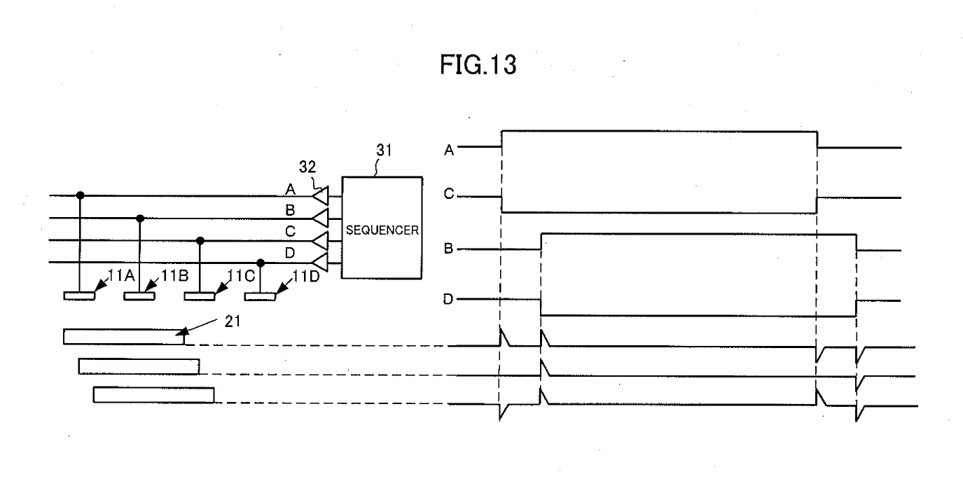

FIG. 13 shows a fourth embodiment of the present invention in which excitation signals different from the excitation signals shown in FIG. 4 are applied to the excitation-electrode sets of the capacitance-type encoder having the hardware configuration shown in FIG. 3.

In the example of FIG. 4, the pulse voltages are applied in the second step after the pulse voltages applied at the first step are returned to zero, however, in the example of FIG. 13, the respective pulses are overlapped.

In the example of FIG. 4, the signal processing section 40 adopts positive voltages of the detection signals SG to be effective, however, in this example, the signal processing section 40 adopts both of the positive and negative voltages of the detection signals SG to be effective.

In the example of FIG. 4, one determination result is obtained by one output of excitation signals, however, according to the way of applying the excitation signals as shown in FIG. 13, two determination results, i.e. a determination result based on the detection signals responding to leading edges of the pulses of the excitation signals, and a determination result based on the detection signals responding to trailing edges of the pulses of the excitation signals, can be obtained.

It should be noted that since the detection signal responding the leading edge and the detection signal responding the trailing edge of the excitation signal are inversed, it is necessary to perform processing of inversing signs of the detection signals responding the trailing edges of the excitation signals or modifying the contents of the stored data, etc.

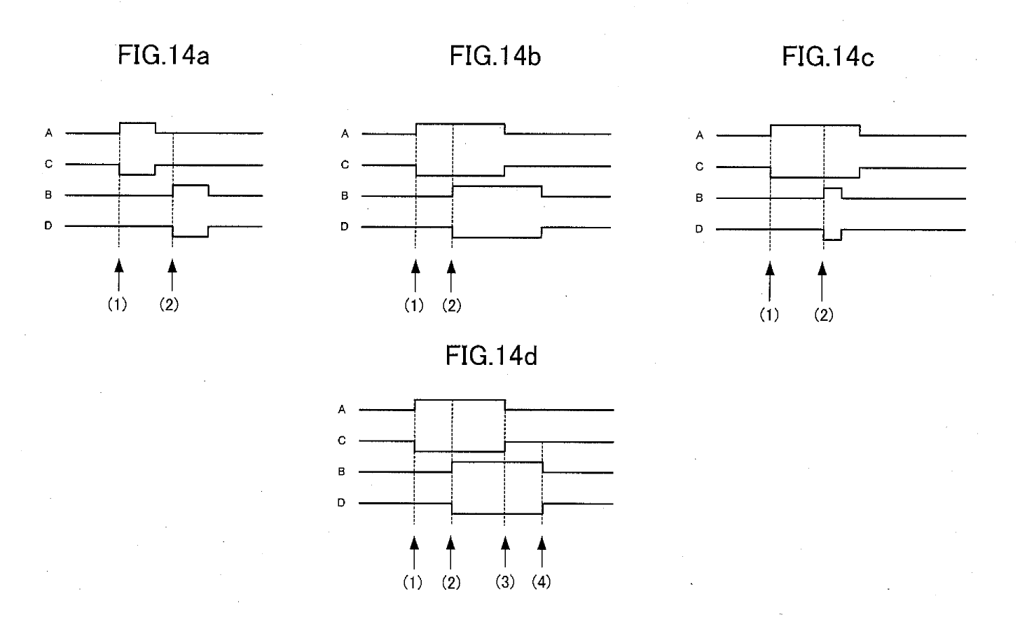

FIGS. 14a-14c show time of acquisitions of (1) the first detection signal and (2) the second detection signal. FIG. 14d shows time of acquisitions of (1) the first detection signal, (2) the second detection signal, (3) the third detection signal and (4) the fourth detection signal.

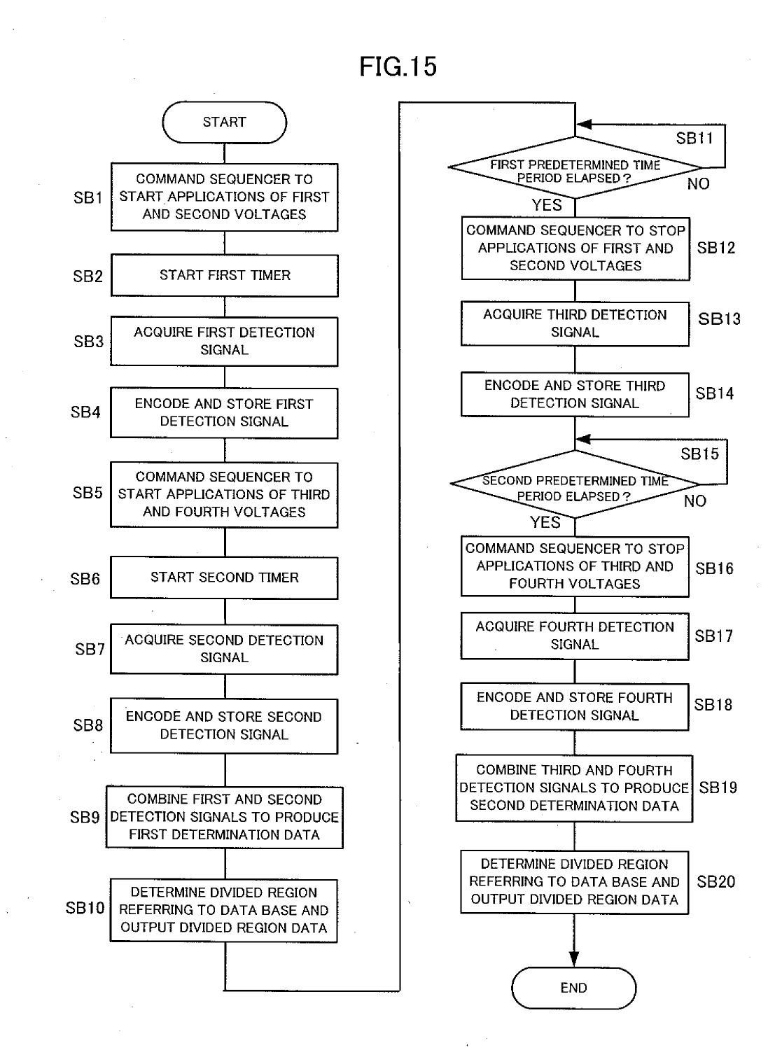

Respective steps of the flowchart shown in FIG. 15 will be explained. This flowchart shows the processing in the fourth embodiment shown in FIG. 13.

[Step SB1]-[Step SB4]: A start of simultaneous application of the first and second voltages is commanded to the sequencer, a first timer to measure a time period elapsed from the start of simultaneous application of the first and second voltages is started, a first detection signal is acquired, and the acquired first detection signal is encoded and stored.

[Step SB5]-[Step SB8]: A start of simultaneous application of the third and fourth voltages is commanded to the sequencer, a second timer to measure a second time period elapsed from the start of simultaneous application of the third and fourth voltages is started, a second detection signal is acquired, and the acquired second detection signal is encoded and stored.

[Step SB9], [Step SB10]: The first detection signal and the second detection signal are combined to produce first determination data and it is determined which divided region the reference line of the connection electrodes is positioned in referring to the data table.

[Step SB11]-[Step SB14]: It is determined whether or not the first timer measured a first predetermined time period and if it is determined that the first predetermined time period has lapsed a stop of the application of the third and fourth voltages is commanded to the sequencer, a third detection signal is acquired, and the acquired third detection signal is encoded and stored.

[Step SB15]-[Step SB18]: It is determined whether or not the second time period has elapsed and if it is determined that the second time period has elapsed a stop of the application of the third and fourth voltages is commanded to the sequencer, a fourth detection signal is acquired, and the acquired fourth detection signal is encoded and stored.

[Step SB19], [Step SB20]: The third detection signal and the fourth detection signal are combined to produce second determination data and it is determined which divided region the reference line of the connection electrodes is positioned in referring to the data table.

What is claimed is:

1. A capacitance-type encoder comprising:
a stator having a plurality of excitation-electrode sets electrically independent from each other and arranged to be displaced to have phase differences from each other, each set being constituted of excitation electrodes arranged cyclically and electrically connected with each other so that a predetermined number of excitation-electrode groups are formed, and having a receiving electrode electrically independent from the excitation electrodes;
a movable element provided movably relative to said stator and having connection electrodes arranged to confront the excitation electrodes of said stator cyclically to have the same number as the excitation-electrode groups, and a sending electrode electrically connected with the connecting electrodes and arranged to confront the receiving electrode of said stator;
excitation means for exciting the excitation electrodes of said stator; and
signal processing means for processing detection signals generated in the connection electrodes of said movable element and received by the receiving electrode through the sending electrode,
wherein in a state where voltages of the excitation electrodes are set to respective reference voltages, said excitation means simultaneously applies a first pulse voltage to one or more of the excitation-electrode sets and a second pulse voltage to one or more of the excitation-electrode sets that have a phase difference of 180 degrees with respect to the one or more excitation-electrode sets to which the first pulse voltage is applied, directions of changes of the first pulse voltage and the second pulse voltage being opposite to each other, and after completion of the applications of the first and second pulse voltages, said excitation means simultaneously applies a third pulse voltage to one or more of the excitation-electrode sets which are different from the excitation-electrode sets to which the first and second pulse voltages are applied and a fourth pulse voltage to one or more of the excitation-electrode sets that have a phase difference of 180 degrees with respect to the one or more of the excitation-electrode sets to which the third pulse voltage is applied, directions of changes of the third pulse voltage and the fourth pulse voltage being opposite to each other, and
said signal processing means stores a first detection signal received by the receiving electrode when the first and second pulse voltages are applied, and stores a second detection signal received by the receiving electrode when the third and fourth pulse voltages are applied, to determine which one of divided regions a reference line of said connection electrodes is positioned in based on a combination of the first and second detection signals, said divided regions being predetermined by dividing one cycle of arrangement of the excitation electrodes in each excitation-electrode group by four.

2. A capacitance-type encoder according to claim 1, wherein said excitation means simultaneously applies the third pulse voltage to one or more of the excitation-electrode sets which have phase differences of 90 degrees with respect to the one or more of the excitation-electrode sets to which the first or second pulse voltage is applied and the fourth pulse voltage to one or more of the excitation-electrode sets which have phase differences of 180 degrees with respect to the one or more of the excitation-electrode sets to which the third pulse voltage is applied.

3. A capacitance-type encoder according to claim 1, wherein said excitation means simultaneously applies the first pulse voltage to one of the excitation-electrode sets and the second pulse voltage to one of the excitation-electrode sets which has a phase difference of 180 degrees with respect to the excitation-electrode set to which the first pulse voltage is applied, and simultaneously applies the third pulse voltage to one of the excitation-electrode sets which has a phase difference of 90 degrees with respect to the excitation-electrode set to which the first or second pulse voltage is applied and the fourth pulse voltage to the excitation-electrode set which has a phase difference of 180 degrees with respect to the excitation-electrode set to which the third pulse voltage is applied.

4. A capacitance-type encoder comprising:
a stator having a plurality of excitation-electrode sets electrically independent from each other and arranged to be displaced to have phase differences from each other, each set being constituted of excitation electrodes arranged cyclically and electrically connected with each other so that a predetermined number of excitation-electrode groups are formed, and having a receiving electrode electrically independent from the excitation electrodes;
a movable element provided movably relative to said stator and having connection electrodes arranged to confront the excitation electrodes of said stator cyclically to have the same number as the excitation-electrode groups, and a sending electrode electrically connected with the connecting electrodes and arranged to confront the receiving electrode of said stator;
excitation means for exciting the excitation electrodes of said stator; and
signal processing means for processing detection signals generated in the connection electrodes of said movable element and received by the receiving electrode through the sending electrode,
wherein in a state where voltages of the excitation electrodes are set to respective reference voltages, said excitation means simultaneously applies a first pulse voltage to one or more of the excitation-electrode sets and a second pulse voltage to one or more of the excitation-electrode sets that are arranged to be equivalent to an arrangement to have a phase difference of 180 degrees with respect to the one or more excitation-electrode sets to which the first pulse voltage is applied, directions of changes of the first pulse voltage and the second pulse voltage being opposite to each other, and after completion of the applications of the first and second pulse voltages, said excitation means simultaneously applies a third pulse voltage to one or more of the excitation-electrode sets which are different from the excitation-electrode sets to which the first and second pulse voltages are applied and a fourth pulse voltage to one or more of the excitation-electrode sets that are arranged to be equivalent to an arrangement to have phase differences of 180 degrees with respect to the one or more of the excitation-electrode sets to which the third pulse voltage is applied, directions of changes of the third pulse voltage and the fourth pulse voltage being opposite to each other, and
said signal processing means stores a first detection signal received by the receiving electrode when the first and second pulse voltages are applied, and stores a second detection signal received by the receiving electrode when the third and fourth pulse voltages are applied, to determine which one of divided regions a reference line of said connection electrodes is positioned in based on a combination of the first and second detection signals, said divided regions being predetermined by dividing one cycle of arrangement of the excitation electrodes in each excitation-electrode group by four.

5. A capacitance-type encoder comprising:
a stator having a plurality of excitation-electrode sets electrically independent from each other and arranged to be displaced to have phase difference from each other, each set being constituted of excitation electrodes arranged cyclically and electrically connected with each other so that a predetermined number of excitation-electrode groups are formed, and having a receiving electrode electrically independent from the excitation electrodes;
a movable element provided movably relative to said stator and having connection electrodes arranged to confront the excitation electrodes of said stator cyclically to have the same number as the excitation-electrode groups, and a sending electrode electrically connected with the connecting electrodes and arranged to confront the receiving electrode of said stator;
excitation means for exciting the excitation-electrode sets of said stator; and
signal processing means for processing detection signals generated in the connection electrodes of said movable element and received by the receiving electrode through the sending electrode,
wherein in a state where voltages of the excitation-electrode sets are set to respective reference voltages, said excitation means simultaneously starts applications of a first voltage to one or more of the excitation-electrode sets and a second voltage to one or more of the excitation-electrode sets that have phase differences of 180 degrees with respect to the one or more of the excitation-electrode sets to which the first voltage is applied, a direction of change to the first pulse voltage from a reference voltage thereof and a direction of change to the second pulse voltage from a reference voltage thereof being opposite to each other, and stops the application of the first and second voltages after a first predetermined time period, after starting the applications of the first and second pulse voltages, said excitation means simultaneously starts applications of a third voltage to one or more of the excitation-electrode sets that are different from the excitation-electrode sets to which the first and second pulse voltages are applied, and a fourth pulse voltage to one or more of the excitation-electrode sets that have phase differences of 180 degrees with respect to the one or more of the excitation-electrode sets to which the third pulse voltage is applied, a direction of change from a reference voltage to the third pulse voltage and a direction of change from a reference voltage to the fourth pulse voltage being opposite to each other, and stops the application of the third and fourth voltages after a second predetermined time period; and
said signal processing means stores a first detection signal received by the receiving electrode when the applications of the first and second excitation signals are started, and stores a second detection signal when the application of the third and fourth excitation signals are started, to determine which one of divided regions said movable element is positioned in based on a combination of the first and second detection signals, said divided regions being predetermined by dividing one cycle of arrangement of excitation electrodes in each excitation-electrode group by four, and further
said signal processing means stores a third detection signal when the applications of the first and second excitation signals are stopped, and stores a fourth detection signal when the applications of the third and fourth excitation signals are stopped, to determine which one of the four divided regions said movable element is positioned in based on a combination of the third and fourth detection signals.

6. A capacitance-type encoder according to claim 5, wherein said excitation means simultaneously starts applications of the third voltage to one or more of the excitation-electrode sets which have phase differences of 90 degrees with respect to the one or more of the excitation-electrode sets to which the first or second voltage is applied and the fourth voltage to one or more of the excitation-electrode sets which have phase differences of 180 degrees with respect to the one or more of the excitation-electrode sets to which the third pulse voltage is applied.

7. A capacitance-type encoder according to claim 5, wherein said excitation means simultaneously starts applications of the first voltage to one of the excitation-electrode sets and the second voltage to one of the excitation-electrode sets which has a phase difference of 180 degrees with respect to the excitation-electrode set to which the first voltage is applied, and simultaneously applies the third voltage to one of the excitation-electrode sets which has a phase difference of 90 degrees with respect to the excitation-electrode set to which the first voltage or the second voltage is applied and the fourth voltage to the excitation-electrode set which has a phase difference of 180 degrees with respect to the excitation-electrode set to which the third voltage is applied.
